(19) United States
(12) Patent Application Publication
(10) Pub. No.: US 2007/0102141 A1
(43) Pub. Date: May 10, 2007

(54) Diversion component

(75) Inventor: Ho-Wen Kuo, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/269,933

(22) Filed: Nov. 8, 2005

(51) Int. Cl. H05K 7/20

(52) U.S. Cl. 165/80.3; 361/690

(57) ABSTRACT

A diversion component connecting to a fixing base for heat sink at least includes a deformable piece and locating portions provided on the piece for connecting the diversion component to the fixing base for heat sink, wherein when the diversion component is connected to the fixing base for heat sink, the piece is deformed to form a choking area for conducting airflow to a desired area.

### BACKGROUND OF THE INVENTION

1. Field of the Invention:

The present invention relates to diversion components and, more particularly to a diversion component for use with a heat sink.

2. Description of Related Art:

Generally, heat dissipating fans such as axial fans, centrifugal fans and the like are often used to conduct airflow to specified channel solve large amount of heat generated by electronic products such as servers and computers. Fans are usually combined with heat dissipating devices (e.g. heat sinks) to guide hot air produced during operation of the electronic products outside so as to dissipate heat effectively. For example, a CPU (Central Process Unit) provided on a motherboard of a computer is often connected to a heat dissipating module including a heat sink and a fan, wherein the heat sink of the heat dissipating module should adhere to the surface of the heat source such as the CPU, so as to lead the heat conducted via the heat sink to outside by the fan. The heat sink as disclosed in TW Utility Model Patent No. 93200168 or No. 91209756 is usually fixed on the motherboard by means of a fixing base for the heat sink with at least one fastener.

Presently, not all CPU sockets are mounted with CPUs on a motherboard having a plurality of CPUs. For instance, sometimes only one socket of a motherboard with dual CPUs is used, whereas the other is idle. However the idle CPU socket may form an area of low flow resistance in relation to the other socket. Accordingly, the cooling airflow forced by the fan may be slowed down while flowing through the low flow resistance area and the heat produced in CPU use cannot be conducted outside effectively, thereby it does not accord with the efficiency demand of heat dissipation, and more particularly, it may cause the computer to be down or even burnt out if a high performance CPU is in use demanding high heat dissipating efficiency.

In order to lead the heat out of the heat source such as a CPU, a diversion structure set on the idle CPU socket is proposed in the TW Utility Model Patent No. 90221926.

As shown in FIG. 5, a heat diversion duct 2 of a computer system disclosed in TW Patent No. 90221926 is covered on a motherboard 8 having a heat source 4 such as a CPU to provide a heat diversion channel. The heat diversion duct 2 includes a body 21, a clasp portion 23, and a nip portion 25. The body 21 has two hollow diversion slots 211, a plurality of elastic hooks 213 and a fixing pole 215, wherein a heat dissipating fans 6 is assembled to one of the hollow diversion slots 211 by the elastic hook 213; the body 21 is locked on the motherboard 8 by locked-in components 27 such as bolts passing through the fixing pole 215 and a through hole 81 of the motherboard 8; and the other hollow diversion slot 211 which covers the idle CPU socket can form a high flow resistance area. The clasp portion 23 is provided near one end of the body 21 for clasping the edge of the motherboard 8. The nip portion 25 is provided to the other side of the body 21, wherein the nip portion 25 is normally in a clasp state but can be actuated to a free state under stress.

However, such heat diversion duct 2 which isolates the whole area by the two hollow diversion slots 211 is complicated in structure and requires assembly mold or extra process, accordingly the manufacture cost is high.

Meanwhile, the heat diversion duct 2 of the prior art cannot accord with the demand of reducing the sizes of all components in the tendency of miniaturized electronic devices because operating area needs to be reserved on the motherboard 8 corresponding to the peripheral of the heat diversion duct 2. Furthermore, assembly and disassembly of this prior-art design is complicated and requires the use of tools.

In addition, such heat diversion duct 2 not only occupies large space of the motherboard as it must cover the whole heat sink (and/or the beat source 4) and the heat dissipating fan 6, but also increases material cost due to its bulk volume.

As a result, the present subject to be solved is how to overcome the above-mentioned defects of the prior art such as complicated structure, difficulty in assembly or disassembly, high manufacture cost, large use of space, limitation in motherboard design, difficulty in reducing the size of motherboard and the like.

### SUMMARY OF THE INVENTION

In view of the above-mentioned problems of the prior art, it is a primary objective of the present invention to provide a diversion component for simplifying structure thereof.

It is another objective of the present invention to provide a diversion component easy in assembly or disassembly.

It is a further objective of the present invention to provide a diversion component for reducing manufacturing cost.

It is still another objective of the present invention to provide a diversion component for reducing occupied space.

It is yet another objective of the present invention to provide a diversion component for freeing the design of motherboard from limitation.

To achieve the above-mentioned and other objectives, a diversion component connecting to a fixing base for heat sink is proposed according to the present invention. In one preferred embodiment, the diversion component comprises a deformable piece and locating portions provided on sides of the piece for detachably connecting the diversion component to the fixing base for heat sink, wherein when the diversion component is connected to the fixing base for heat sink, the piece is deformed to form a choking area which can conduct airflow to a specified area.

The above-mentioned piece is an elastic piece made of elastic material, and more preferably is a plastic piece or an elastic piece made of composite material. The locating portions are preferably step-like sections which extend and bend from two sides of the piece. The diversion component of the present invention which is characterized by the deformable piece can be mounted on different fixing bases for heat sinks in different sizes; thereby the diversion component can greatly save cost of manufacturing, management and storage. Additionally, the thickness of the locating portion is smaller than the height of a fixing portion of the fixing base for heat sink, such that the diversion component can combine with the fixing base for heat sink conveniently without providing another fixing portion or intervening fasteners of the fixing base for heat sink, moreover the diversion component can be assembled or disassembled without aiding tools.

Since the simple-structured piece of the diversion component can form a diversion area for conducting cooling airflow to the working CPU and CPU socket in use, and the locating portions can be assembled or disassembled without any tools. Accordingly, the diversion component of the present invention can simplify structure, make it easy in assembly or disassembly, reduce manufacturing cost, reduce occupied space and free motherboard design from limitation.

Meanwhile, the diversion component of the present invention can be directly applied in the current fixing module and fixing base for heat sink without the need for tailored fixing structure. Thus, the present invention has wide industrial application.

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### BRIEF DESCRIPTIONS OF THE DRAWINGS

FIG. 1A to FIG. 1C are plane views of a diversion component of the present invention;

FIG. 2 is a schematic diagram showing a use state of the diversion component according to the present invention;

FIG. 3 is a schematic diagram showing a structure of TW Utility Model Patent No. 91209756 to which the diversion component of the present invention can be applied;

FIG. 4 is a schematic diagram showing a structure of TW Utility Model Patent No. 93200168 to which the diversion component of the present invention can be applied; and

FIG. 5 is a schematic diagram showing a structure of TW Utility Model Patent No. 90221926.

### DETAILED DESCRIPTIONS OF PREFERRED EMBODIMENTS

The following embodiments are provided to further describe the technical instruments of the present invention; however they are not limited to the present invention.

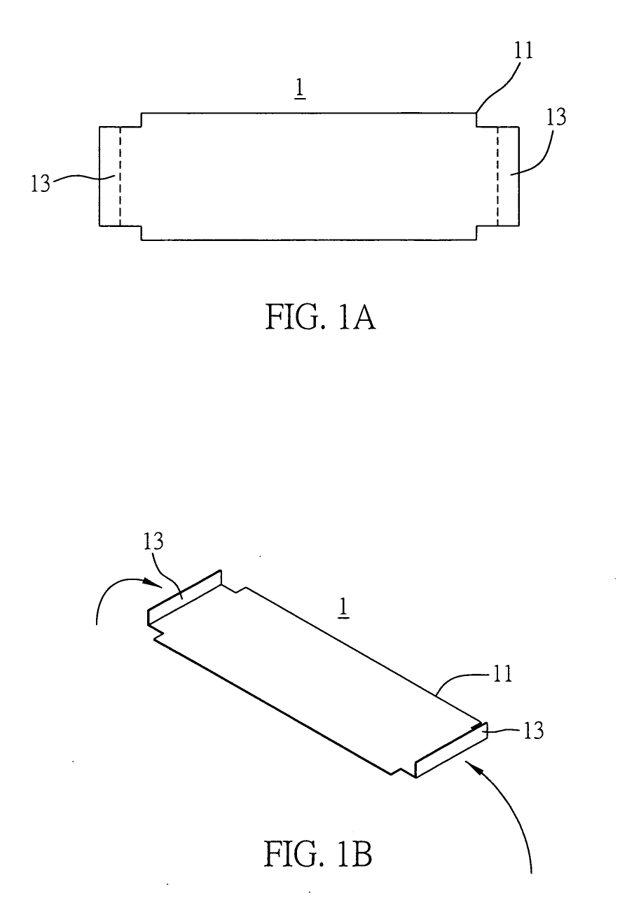

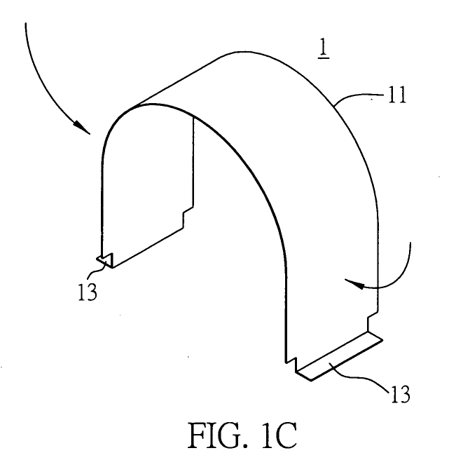

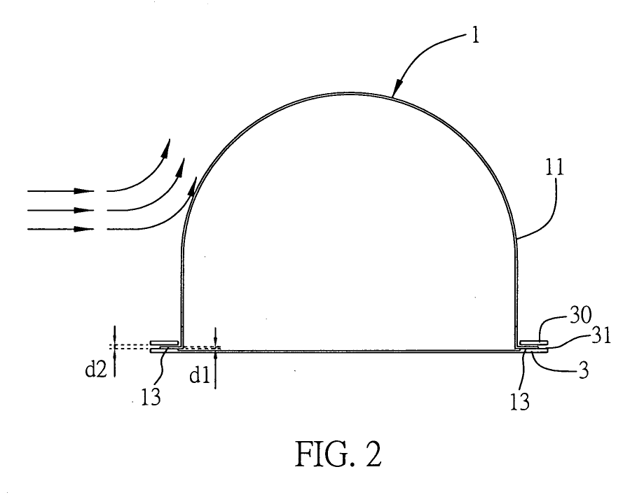

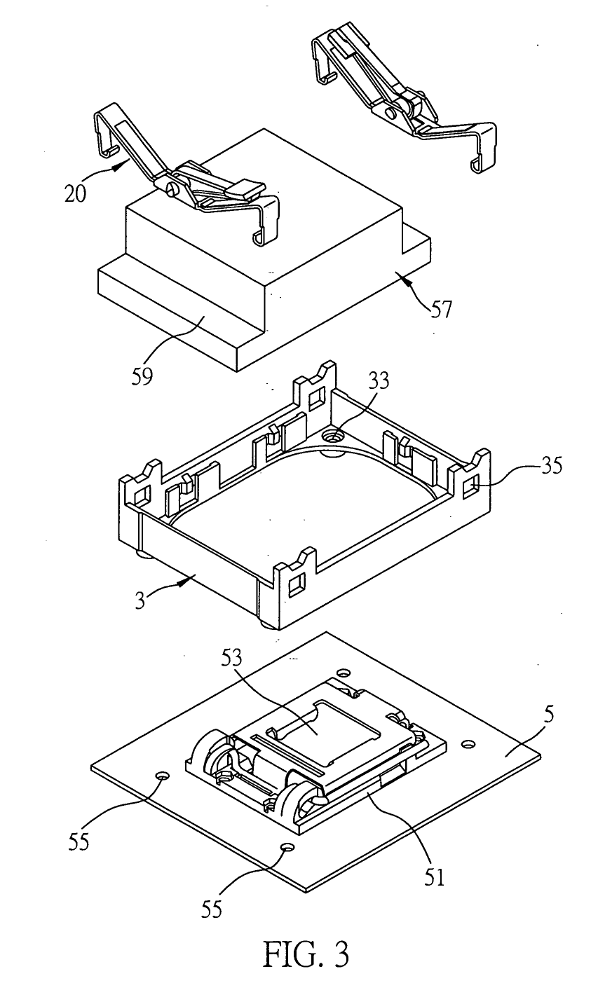

FIG. 1A to FIG. 1C are plane views of a diversion component of the present invention and FIG. 2 is a cross-sectional view showing a use state of the diversion component. As shown in the figure, the diversion component 1 of the present invention which is to be assembled to a fixing base for heat sink 3 at least includes a deformable piece 11 and two locating portions 13 provided on two sides of the piece 11.

As shown in FIG. 1A to FIG. 1C, the piece 11 is an elastic piece made of elastic material such as plastic, composite material and the like. In this embodiment, the shape of the piece 11 is rectangular, but it is not limited thereto. It should be understood to those in the art that any variations of the piece 11 can be used in the present invention as long as the piece can form a choke area in accordance with the flow direction of airflow for conducting cooling airflow to the CPU socket in use as mentioned above (including the CPU and the heat sink).

Referring to FIG. 1A to FIG. 1C, the locating portions 13 are provided on the two sides of the piece 11. In this embodiment, the locating portions 13 are stepped sections which extend and bend from the two sides of the piece 11. For example, as shown in FIG. 1A, a rectangular piece 11 is provided and the two sides of the piece 11 are clipped to form the locating portions 13 as shown in FIG. 1B; alternatively, the locating portions 13 can be formed at the two sides of the piece 11 by injection molding. Certainly, other equivalent methods can be used to fabricate the diversion component of the present invention. As shown in FIG. 1C, the locating portions 13 are folded in the same direction, and the piece 11 is bent to the inverse direction without forming a fold line such that the piece 11 can resile to its original shape for it has an elastic restoring force.

While combining the diversion component of the present invention to the fixing base for heat sink, referring to FIG. 2, the locating portions 13 are inserted into fixing portions 31 of the fixing base for heat sink 3. As the piece 11 has elasticity of outward tension, fasteners 30 for fixing the heat sink (not shown in the figure) can be braced without the fasteners 30 clamping the piece 11 and furthermore the piece 11 can form a choke area.

In this embodiment, the thickness d1 of the locating portion 13 is smaller than the height d2 of the fixing portion 31 of the fixing base for heat sink 3. Certainly, the thickness d1 of the locating portion 13 can equal to that of the piece 11, i.e. the thickness of the piece 11 is smaller than the height d2 of the fixing portion 31 of the fixing base for heat sink 3. Although the thickness d1 of the locating portion 13 is equal to that of the piece 11 in one preferred embodiment, it is not limited thereto and locating portion 13 with any thickness can be applied in the present invention as long as it can be inserted into the fixing portion 31 between the fixing base for heat sink 3.

It follows that the diversion component of the present invention which is characterized by simple structure and single size can be mounted on different fixing bases for heat sink with different sizes. Compared to the prior art, defects that it is complicated in structure fabricated by injection molding or extra process and different sizes of the diversion component must be tailored to different fixing base for heat sink can be solved, so manufacture cost can be reduced greatly.

Meanwhile, the diversion component of the present invention can be assembled or disassembled without any tools and minimize the occupied area, accordingly problems of the prior art such as difficulty in assembly or disassembly with tools, limitation of motherboard design, large volume of the motherboard, difficulty in miniaturization and the like can be overcome by the present invention, moreover material and occupied space can also be saved.

It should be noted that the diversion component of the present invention is combined to a fixing base for heat sink such as the one shown in the prior art for forcing the piece to form a choke area. Descriptions showing the usage of the present invention are illustrated in the following embodiments. As the structures of the motherboard, the CPU and the heat dissipating module (generally including a heat sink and a fan) are the same as those of the prior art, only associated components and structures of the present invention are shown in the drawings and the detailed descriptions of others are omitted in order to make the disclosure of the present invention easier to be understood.

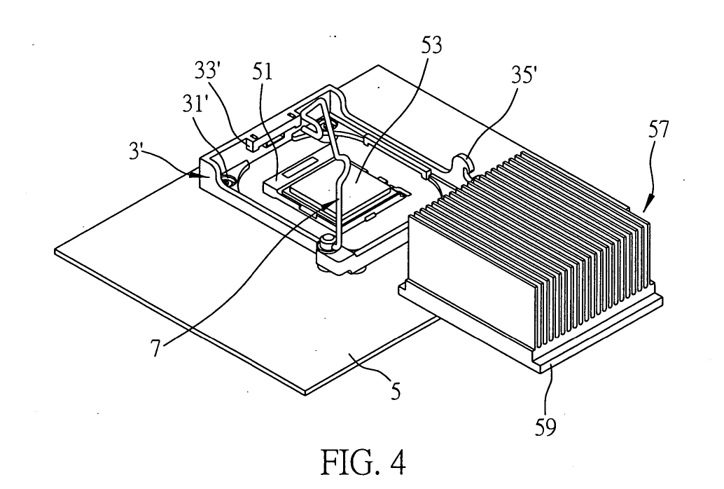

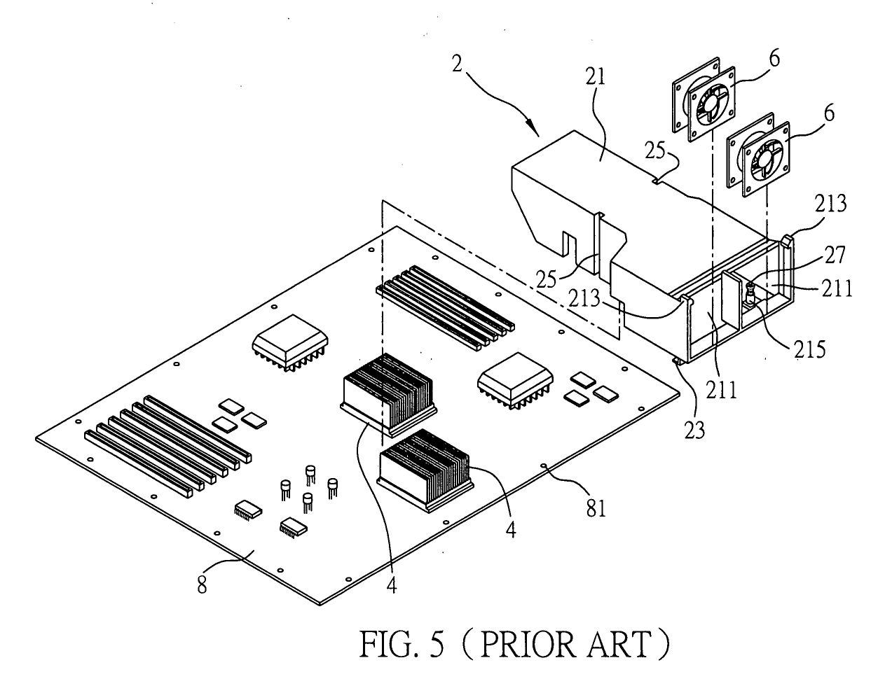

As shown in FIG. 3, the diversion component 1 can be applied to combine with a fixing module for a heat sink disclosed in TW Utility Model Patent No. 91209756. The fixing module which is used to fix a heat sink 57 on a motherboard 5 includes a fixing base for a heat sink 3 and two elastic arms 20 (similar to the fasteners 30 of FIG. 2). A CPU socket 51 (for example, PGA-370) is generally provided on the motherboard 5 for receiving the CPU 53 and standard locating holes 55 are provided on the motherboard 5 corresponding to the surroundings of the CPU socket 51. The heat sink 57 usually has extended bottom wings 59 for providing pressure points.

The fixing base for heat sink 3 has a framing structure for carrying and laterally orienting the heat sink 57. Lock holes 33 corresponding to the locating holes 55 are provided on the fixing base for heat sink 3 for assembling the fixing base for heat sink 3 to the periphery of the CPU socket 51 on the motherboard 53 by securing components such as screws or bolts. At the same time, a plurality of fasten holes 35 is also provided on the outline of the fixing base for heat sink 3 for the two elastic arms 20 to clasp correspondingly. The elastic arms 20 are made of metal elastic pieces, which are pressed against both bottom wings 59 of the heat sink 57. Additionally, the width of the locating portions 13 can approximately equal to the width of the bottom wings 59 of the heat sink 57 so they can be inserted into the gaps under the elastic arms which are originally used for clasping the bottom wings 59 of the heat sink 57. As the thickness d1 of the locating portions 11 is smaller than the height d2 of the fixing portions 31, i.e. the thickness d1 of the locating portions 11 is smaller than the height between the fixing base for heat sink 3 and the elastic arms 20, so that the locating portions 11 can be directly inserted into the fixing portions 31 without opening the elastic arm 20 and the piece 11 can be braced on the fixing base for heat sink 3.

There are gaps, i.e. abovementioned fixing portions 31, between the elastic arms 20 and the fixing base for heat sink 3 after the elastic arms 20 clasp the outline of the fixing base for heat sink 3 that are used for fastening the locating portions 13 of the diversion component 1 to the fixing base for a heat sink 3, allowing the piece 11 to form the choke area.

As shown in FIG. 4, the diversion component 1 can also be combined with a fixing device for heat sink disclosed in TW Utility Model Patent No. 93200168. The fixing device for heat sink which is used to fix a heat sink 57 on a motherboard 5 (same reference numbers are shown in the figure for simplification as the same motherboard and the heat sink are used) includes a fixing base for heat sink 3′ and an elastic arm 7 (equivalent to the fasteners 30 shown in FIG. 2). A CPU socket 51 (for example, PGA-370) is also provided on the motherboard 5 for receiving the CPU 53 and the heat sink 57 also has extended bottom wings 59.

The fixing base for heat sink 3′ has a framing structure for carrying and partly orienting the heat sink 57. A plurality of lock holes 31′ are provided on the fixing base for heat sink 3′ for assembling the fixing base for heat sink 3′ to the periphery of the CPU socket 51 on the motherboard 5 by fastening components such as screws or bolts. Moreover, a locating portion 33′ is provided on one side of the outline of the fixing base for heat sink 3′ for locating one of the bottom wings 59 of the heat sink 57, a hook portion 35 is provided on a corner of the other side of the outline and the elastic arm 7 which can be turned to hook the hook portion 35 is set on another corner of the other side of the outline. The elastic arm 7 is made of metal slender rod for pressing against the other one of the bottom wings 59 of the heat sink 57.

Similarly, a fixing base for heat sink 3′ with only one elastic arm 7 is used to fix the heat sink, but as the fixing base for heat sink 3′ still retains the fixing portions 31 mentioned above, the diversion component 1 of the present invention can also be applied to the fixing base for heat sink 3′ and the locating portion 11 can be directly inserted underneath the fixing base for heat sink 3′ without opening the elastic arm 7 so as to allow the piece 11 to form a choke area.

Furthermore, although fixing bases for heat sink with at least one fastener in the above embodiments are used to illustrate the applications of the diversion component of the present invention, it should be noted that the diversion component can be applied in different structures of fixing bases for heat sinks, for example, it can applied to fixing components that separately join the bottom wings of the heat sink, wherein the fixing components are used to fix the heat sink on a surface and connecting holes are provided on both of the bottom wings; moreover the fixing component may include a body, a locating portion provided on the bottom of the body and a screwing portion on the body for combining the fixing component to the bottom wings by a screwing component, thus the present invention is not limited to specific fixing bases for heat sinks.

As a result, the diversion component of the present invention can block airflow via the bent piece and can be fixed via the locating portion without the use of fixing tools. Accordingly, the diversion component of the present invention can reduce material consumption, simplify structure, reduce manufacture cost greatly and make it easy in assembly or disassembly. Furthermore, defects of the prior art such as limitation of motherboard design and difficulty in minimizing the motherboard can be solved effectively as the structure and the size of the diversion component is smaller; meanwhile the diversion component has wide industrial application for it can be applied in new and present fixing modules for heat sinks.

The foregoing descriptions of the detailed embodiments are only to illustrate the features and functions of the present invention and not restrictive of the scope of the present invention. It should be understood to those in the art that all modifications and variations according to the spirit and principle in the disclosure of the present invention should fall within the scope of the appended claims.

What is claimed:

1. A diversion component connecting to a fixing base for a heat sink, comprising:
a deformable piece; and
at least a locating portions formed at sides of the deformable piece for detachably connecting the diversion component to the fixing base for the heat sink, wherein when the diversion component is connected to the fixing base for the heat sink, the piece is deformed to form a choking area for conducting airflow to a specified area.

2. The diversion component of claim 1, wherein the piece is an elastic piece made of elastic material.

3. The diversion component of claim 1, wherein the piece is a plastic piece.

4. The diversion component of claim 1, wherein the piece is an elastic piece made of composite material.

5. The diversion component of claim 1, wherein the locating portions are stepped sections which extend and bend from two sides of the piece.

6. The diversion component of claim 1, wherein the thickness of the locating portion is smaller than the height of a fixing portion of the fixing base for heat sink.
